(19) United States
(12) Patent Application Publication
(10) Pub. No.: US 2014/0166075 A1
(43) Pub. Date: Jun. 19, 2014

(54) METHODS AND SYSTEMS FOR TEMPERATURE REGULATION DEVICES

(71) Applicant: SUNEDISON LLC, Beltsville, MD (US)

(72) Inventors: Sandeep Rammohan Koppikar, Bangalore (IN); Marath Prakash, Bangalore (IN); Nagendra Srinivas Cherukupalli, Cupertino, CA (US)

(21) Appl. No.: 14/106,437

(22) Filed: Dec. 13, 2013

Related U.S. Application Data
(60) Provisional application No. 61/737,582, filed on Dec. 14, 2012.
(60) Provisional application No. 61/759,109, filed on Jan. 31, 2013.

(51) Int. Cl. H01L 31/052

(52) U.S. Cl. CPC H01L 31/0521
USPC 136/246; 165/168

(57) ABSTRACT

A heat exchanger for coupling to a device is described. The heat exchanger includes an inner layer configured for placement against at least one surface of the device, an outer layer opposite the inner layer, a fluid chamber defined between the outer layer and the inner layer, an inlet for directing a thermal transfer fluid into the fluid chamber, an outlet for receiving the thermal transfer fluid from the fluid chamber, and at least one filler within the fluid chamber. The filler is coupled to the outer layer and the inner layer and configured to control a flow of the thermal transfer fluid between the inlet and the outlet.

### CROSS-REFERENCE TO RELATED APPLICATIONS

This application claims priority to U.S. Provisional Application No. 61/737,582 filed Dec. 14, 2012 and U.S. Provisional Application No. 61/759,109 filed Jan. 31, 2013, the entire disclosures of which are hereby incorporated by reference in their entireties.

### FIELD

This disclosure generally relates to temperature regulation, and more specifically, to methods and systems for regulating temperature using a multilayered heat exchanger.

### BACKGROUND

Various devices can benefit from temperature regulation. In particular, many electronic and/or electrical devices benefit from temperature reduction and/or limiting temperature increases. For example, photovoltaic (PV) modules are devices which convert solar energy into electricity. Some known PV modules convert around 85% of incoming sunlight into heat. During peak conditions, this can result in a heat-generation of 850 W/m² and PV module temperatures as high as 70° C. The electrical power produced by PV modules decreases linearly with increase in module temperature. For example, in bright sunlight, crystalline silicon PV modules may heat up to 20-30° C. above ambient temperature, resulting in a 10-15% reduction in power output relative to the rated power output for the PV module. Moreover, higher PV module temperatures may increase material degradation, such as thermal fatigue failure of interconnections between PV cells in the PV module. Accordingly, PV modules may benefit from reduced temperatures and/or from reducing a rate of increase in temperature.

This Background section is intended to introduce the reader to various aspects of art that may be related to various aspects of the present disclosure, which are described and/or claimed below. This discussion is believed to be helpful in providing the reader with background information to facilitate a better understanding of the various aspects of the present disclosure. Accordingly, it should be understood that these statements are to be read in this light, and not as admissions of prior art.

### BRIEF SUMMARY

According to one aspect of this disclosure, a photovoltaic (PV) module includes a solar panel having a top surface and a bottom surface, and a heat exchanger in thermal communication with the bottom surface of the solar panel. The heat exchanger includes an outer layer, a fluid chamber defined between the outer layer and the bottom surface of the solar panel, an inlet for directing a thermal transfer fluid into the fluid chamber, an outlet for receiving the thermal transfer fluid from the fluid chamber, and at least one spacer within the fluid chamber. The spacer is configured to control a flow of the thermal transfer fluid between the inlet and the outlet.

In another aspect, a PV system includes a fluid pump, a fluid heat exchanger configured to thermally alter a thermal transfer fluid and provide the thermal transfer fluid to the fluid pump, and a PV module coupled to the fluid pump and the fluid heat exchanger. The PV module is configured to receive the thermal transfer fluid from the pump. The PV module includes a solar panel having a top surface and a bottom surface, and a heat exchanger in thermal communication with the bottom surface of the solar panel. The heat exchanger includes a fluid chamber having at least one spacer within the fluid chamber. The heat exchanger is configured to receive the thermal transfer fluid from the fluid pump into the fluid chamber and output the thermal transfer fluid to the fluid heat exchanger after the thermal transfer fluid has passed through the fluid chamber.

Yet another aspect is a heat exchanger for coupling to a device to regulate a temperature of the device. The heat exchanger includes an inner layer configured for placement against at least one surface of the device, an outer layer opposite the inner layer, a fluid chamber defined between the outer layer and the inner layer, an inlet for directing a thermal transfer fluid into the fluid chamber, an outlet for receiving the thermal transfer fluid from the fluid chamber, and at least one spacer within the fluid chamber. The spacer is coupled to the outer layer and the inner layer and configured to control a flow of the thermal transfer fluid between the inlet and the outlet.

Various refinements exist of the features noted in relation to the above-mentioned aspects. Further features may also be incorporated in the above-mentioned aspects as well. These refinements and additional features may exist individually or in any combination. For instance, various features discussed below in relation to any of the illustrated embodiments may be incorporated into any of the above-described aspects, alone or in any combination.

### BRIEF DESCRIPTION OF THE DRAWINGS

FIG. 1 is a perspective view of an example PV module;

FIG. 2 is a cross-sectional view of the PV module shown in FIG. 1 taken along the line A-A;

FIG. 3 is a cross-sectional view of an exemplary heat exchanger;

FIG. 4 is a temperature regulation system including the heat exchanger shown in FIG. 3;

FIG. 5 is a cross-sectional illustration of an assembly including a heat exchanger attached to a PV module;

FIG. 6 is a top view of an assembly including a heat exchanger integrated into a PV module;

FIG. 7 is a cross sectional view of the assembly shown in FIG. 6 taken along the line A-A in FIG. 6;

FIG. 8 is a top view of an exemplary stand-alone heat exchanger;

FIG. 9 is a cross sectional view of heat exchanger shown in FIG. 8 taken along the line B-B in FIG. 8;

FIG. 10 is a top view of a heat exchanger including a plurality of plastic spacers;

FIG. 11 is a cross sectional view of heat exchanger shown in FIG. 10 taken along the line C-C in FIG. 10;

FIG. 12 is a cross sectional view of an exemplary connection assembly for use as an inlet and/or outlet for a heat exchanger; and

FIG. 13 is a heat exchanger coupled to a device.

Like reference symbols in the various drawings indicate like elements.

### DETAILED DESCRIPTION

The embodiments described herein generally relate to temperature regulation and control. More specifically, embodiments described herein relate to methods and systems for regulating and controlling temperature using a multilayered heat exchanger. Specific embodiments are described herein with reference to photovoltaic (PV) modules. However, the teachings of the present disclosure may be applied to any device that may benefit from enhanced temperature regulation. Moreover, although various embodiments will be discussed with respect to cooling a device, it should be understood that the embodiments described herein may additionally, or alternatively, be used to heat a device with which they are used.

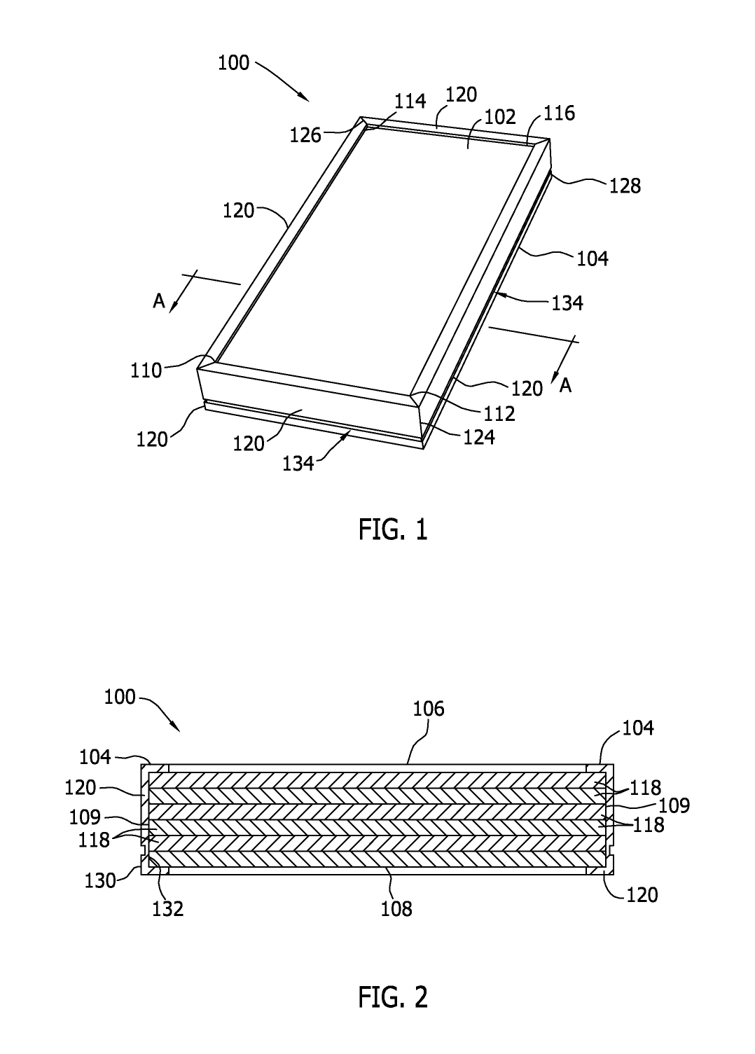

Referring initially to FIGS. 1 and 2, a PV module is indicated generally at 100. A perspective view of PV module 100 is shown in FIG. 1. FIG. 2 is a cross sectional view of PV module 100 taken at line A-A shown in FIG. 1. PV module 100 includes a solar panel 102 and a frame 104 circumscribing solar panel 102.

Solar panel 102 includes a top surface 106 and a bottom surface 108 (shown in FIG. 2). Edges 109 extend between top surface 106 and bottom surface 108. In this embodiment, solar panel 102 is rectangular shaped. In other embodiments, solar panel 102 may have any suitable shape.

As shown in FIG. 2, this solar panel 102 has a laminate structure that includes several layers 118. Layers 118 may include for example glass layers, non-reflective layers, electrical connection layers, n-type silicon layers, p-type silicon layers, and/or backing layers. In other embodiments, solar panel 102 may have more or fewer, including one, layers 118, may have different layers 118, and/or may have different types of layers 118.

As shown in FIG. 1, frame 104 circumscribes solar panel 102. Frame 104 is coupled to solar panel 102, as best seen in FIG. 2. Frame 104 assists in protecting edges 109 of solar panel 102. In this embodiment, frame 104 is constructed of four frame members 120. In other embodiments frame 104 may include more or fewer frame members 120.

Exemplary frame 104 includes an outer surface 130 spaced apart from solar panel 102 and an inner surface 132 adjacent solar panel 102. Outer surface 130 is spaced apart from and substantially parallel to inner surface 132. In this embodiment, frame 104 is made of aluminum. More particularly, in some embodiments frame 104 is made of 6000 series anodized aluminum. In other embodiments, frame 104 may be made of any other suitable material providing sufficient rigidity including, for example, rolled or stamped stainless steel, plastic, or carbon fiber.

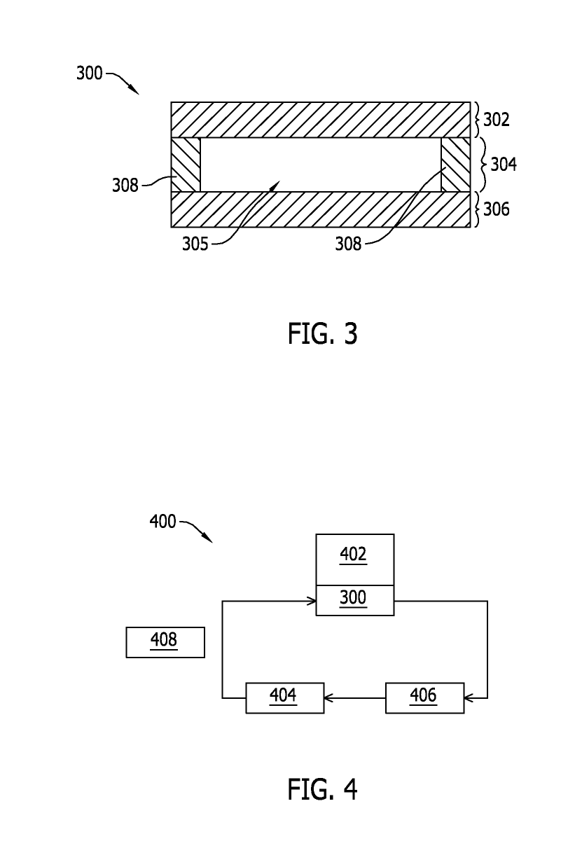

FIG. 3 is a simplified cross-sectional view of an exemplary heat exchanger 300 according to the present disclosure. Heat exchanger 300 includes an inner layer 302, a fluid layer 304, and an outer layer 306. In this embodiment, fluid layer 304 includes a chamber 305 and one or more spacers or spacing material (not shown in FIG. 3) to maintain a substantially consistent separation between inner and outer layers 302 and 306. The spacers are connected to inner layer 302 and outer layer 306 to, among other things, prevent bulging of inner or outer layer 302 or 306 when fluid is pumped into chamber 305 of fluid layer 304. Seals 308 connect inner and outer layers 302 and 306 to provide a substantially water tight seal around fluid layer 304, and more specifically around chamber 305. Thus, a heat transfer fluid, such as water, oil, etc., may flow through fluid layer 304 to extract heat from a device with which heat exchanger 300 is used, without the fluid contacting the device. In some embodiments, seals 308 may be, additionally or alternatively, spacers or spacing material. Moreover, in some embodiments, seals 308 may be integrally formed with inner layer 302 and/or outer layer 306.

Inner layer 302 is the portion of heat exchanger 300 that will be in contact with the device to be temperature regulated by heat exchanger 300. Accordingly, inner layer 302 is made from a material having relatively high thermal conductivity. Moreover, the material for inner layer 302 is selected to conform reasonably well to the surface of the device with which it will be used in order to provide sufficient thermal contact or thermal communication with the surface of the device. In this embodiment, inner layer 302 comprises a sheet that is suitably made of metal. In other embodiments, inner layer 302 may be an aluminum sheet.

The thickness of inner layer 302 may be varied to suit different uses. Thicker sheets may be used to provide increased rigidity and thermal transfer, but with a corresponding decrease in flexibility and/or conformability. In some embodiments, inner layer 302 is a thin, metal foil. In one exemplary embodiment, inner layer 302 is a metal foil having a thickness of about 0.1 millimeter. Other embodiments may use thicker or thinner metal foils. The use of thinner materials for inner layer 302 may increase the flexibility of heat exchanger 300, reduce the weight of heat exchanger 300, and/or permit it to conform to more irregular shaped devices. In general, inner layer 302 may be constructed from any thermally conductive material of sufficient strength and impermeability to retain a heat transfer fluid within heat exchanger 300.

Outer layer 306 is the portion of heat exchanger 300 opposite the side of heat exchanger 300 that will be in contact with the device to be temperature regulated by heat exchanger 300 (i.e., opposite inner layer 302). In some embodiments, outer layer 306 is made of a material having relatively high thermal conductivity, such as a metal sheet or a metal foil, to permit heat to radiate from fluid layer 304 through outer layer 306. In other embodiments, outer layer is fabricated from a material that is not particularly thermally conductive, such as a plastic sheet or film. The thickness of outer layer 306 may be varied to suit different uses. Thicker sheets may be used to provide increased rigidity and thermal transfer, but with a corresponding decrease in flexibility and/or conformability. In some embodiments, outer layer 306 is a thin, metal foil. In other embodiments, outer layer 306 is a thin sheet that is suitably made of plastic. The use of thinner materials for outer layer 306 may increase the flexibility of heat exchanger 300, reduce the weight of heat exchanger 300, and/or permit it to conform to more irregular shaped devices. In general, outer layer 306 may be made of any material of sufficient strength and impermeability to retain a heat transfer fluid within heat exchanger 300.

FIG. 4 is a simplified diagram of a closed loop temperature control or regulation system 400 including heat exchanger 300 (heat exchanger may alternatively be referred to as a meshplate). Heat exchanger 300 is coupled to a device 402 that may benefit from temperature regulation provided by heat exchanger. In this embodiment, device 402 is a device, such as PV module 100, that generates heat and heat exchanger 300 is used to reduce the temperature and/or slow the rise in temperature of device 402. In other embodiments, heat exchanger 300 may be used to increase the temperature of device 402 and/or slow the decrease in temperature of device.

In this embodiment, a pump 404 pumps a thermal transfer fluid (e.g., a coolant) to an inlet (not shown in FIG. 4) of heat exchanger 300. The transfer fluid passes into chamber 305 of fluid layer 304 through the inlet. Within chamber 305, the thermal transfer fluid draws off heat from device 402, via thermal conduction through connection of inner layer 302 to device 402. The thermal transfer fluid exits heat exchanger 300 via an outlet (not shown in FIG. 4) and is directed to a fluid heat exchanger 406. Fluid heat exchanger 406 may be any heat exchange device suitable for extracting the heat carried by the thermal transfer fluid. For example, fluid heat exchanger may be a radiator, an extended length of thermally conductive conduit, a condenser, etc. Moreover, in some embodiments fluid heat exchanger 406 may be part of another system, such that heat extracted from thermal transfer fluid may be used by the other system. In one example embodiment fluid heat exchanger 406 is a radiator used to warm the air inside a structure. In another embodiment fluid heat exchanger 406 is used to heat water.

As will be readily understood by those of ordinary skill in the art, system 400 may, additionally or alternatively, be used to heat device 402. In such embodiments, thermal transfer fluid having a temperature greater than device 402 is pumped by pump 404 to heat exchanger 300. Within chamber 305, the thermal transfer fluid loses its heat to device 402, via conduction through inner layer 302. Fluid heat exchanger 406 then increases the temperature of the heat transfer fluid before pump 404 returns the fluid to heat exchange device 300. A single system 400 may be used to selectively heat or cool device 402 through use of a dual purpose fluid heat exchanger 406 or separate, selectable, fluid heat exchangers 406: one for heating the thermal fluid and another for cooling the thermal fluid. Thus, device 402 may be cooled by system 400 when temperatures are relatively high, and warmed by system 400 when temperatures are relatively cool.

A controller 408 controls operation of system 400. More specifically, controller 408 controls operation of system 400 to obtain a desired amount of cooling and/or heating of device 402. In some embodiments, controller 408 may monitor a temperature of device 402 with a sensor (not shown). Other embodiments do not include controller 408. In this embodiment, controller 408 is configured to control operation of pump 404. Controller 408 may operate pump 404 continuously, intermittently, and/or may pulse pump 404 to achieve a desired heating/cooling of device 402. In some embodiments, controller 408 may additionally, or alternatively, control operation of fluid heat exchanger 406 and/or heat exchanger 300. In still other embodiments, controller 408 may also control operation of device 402. For example, controller 408 may be a PV system controller that controls operation of a direct current (DC) to alternating current (AC) power converter extracting power from a PV module device 402.

Controller 408 may be any suitable controller, including any suitable analog controller, digital controller, or combination of analog and digital controllers. In some embodiments, controller 408 includes a processor (not shown) that executes instructions for software that may be loaded into a memory device. The processor may be a set of one or more processors or may include multiple processor cores, depending on the particular implementation. Further, the processor may be implemented using one or more heterogeneous processor systems in which a main processor is present with secondary processors on a single chip. In another embodiment, the processor may be a homogeneous processor system containing multiple processors of the same type. In some embodiments, controller 408 includes a memory device (not shown). As used herein, a memory device is any tangible piece of hardware that is capable of storing information either on a temporary basis and/or a permanent basis. The memory device may be, for example, without limitation, a random access memory and/or any other suitable volatile or non-volatile storage device. The memory device may take various forms depending on the particular implementation, and may contain one or more components or devices. For example, the memory device may be a hard drive, a flash memory, a rewritable optical disk, a rewritable magnetic tape, and/or some combination of the above. The media used by memory device also may be removable. For example, without limitation, a removable hard drive may be used for the memory device.

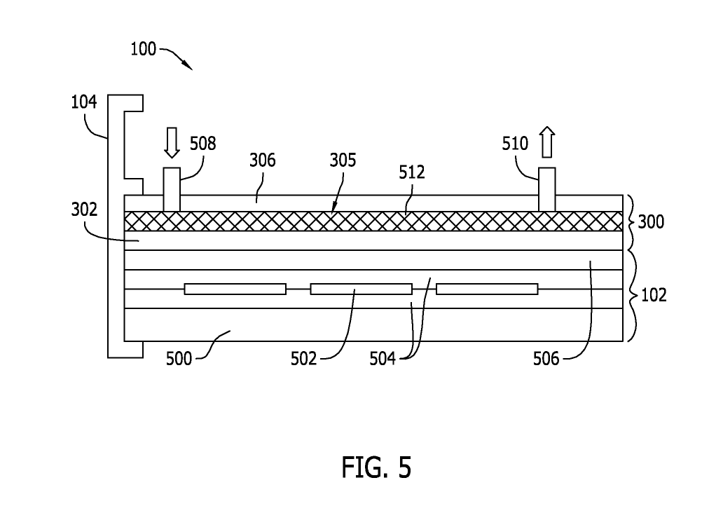

FIG. 5 is a cross-sectional illustration of an exemplary assembly including heat exchanger 300 attached to PV module 100.

In this embodiment, solar panel 102 includes a front glass 500, solar cells 502 surrounded by an encapsulant 504, and a back sheet 506. In this embodiment, the encapsulant 504 comprises ethylene vinyl acetate (EVA). In other embodiments, any other suitable encapsulant may be used. In this embodiment, back sheet 506 is a polyvinyl fluoride (PVF) material. In other embodiments, back sheet 506 may be any other suitable back sheet material or a laminate of materials, including, for example a laminate of PVF surrounding a polyester material.

Thermal transfer fluid enters heat exchanger 300 via inlet 508 and passes through chamber 305 to outlet 510. A spacer 512 is contained within chamber 305. Spacer 512 separates inner and outer layers 302 and 306 and slows the flow of the thermal transfer fluid through chamber 305 to permit the thermal transfer fluid to absorb heat from solar panel 102. In this embodiment, spacer 512 includes a mesh. More specifically, spacer 512 is a woven mesh. In other embodiments, spacer 512 may include a non-woven mesh, a sponge, spacer strips, capillary tubes, or some combination of the above. In this embodiment, mesh 512 is attached to inner and outer layers 302 and 306 and substantially fills chamber 305.

Heat exchanger 300 may be permanently or semi-permanently integrated into PV module 102, or may be a standalone component that may be removably attached to a device. A standalone heat exchanger 300 may be coupled to device 402 by any suitable means to provide a thermally connection between inner layer 302 and a surface of device 402. In some embodiments, heat exchanger 300 is connected to device 402 using a thermally conductive adhesive, including for example a double-sided, thermally conductive tape.

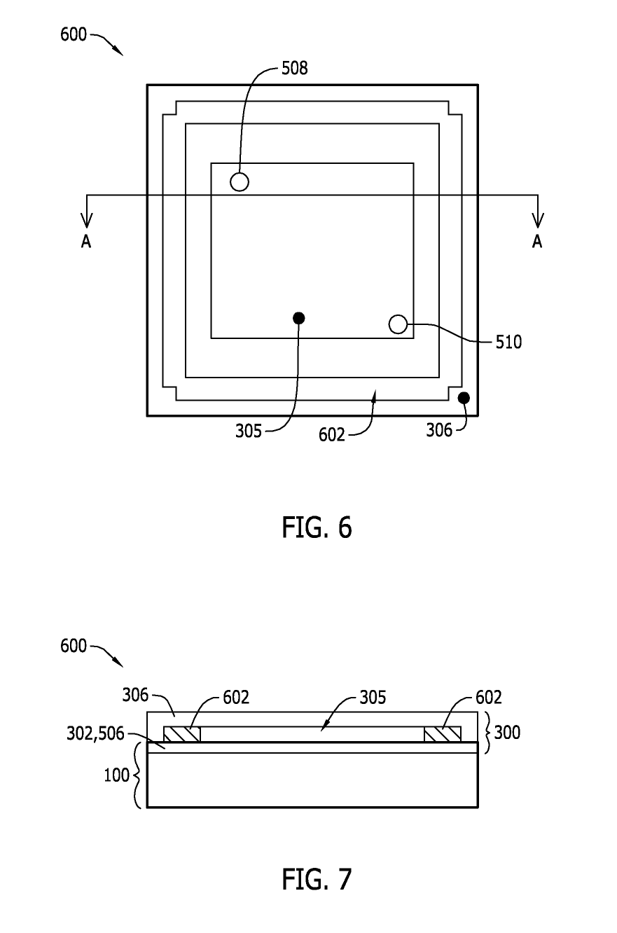

FIG. 6 is a top view of an exemplary assembly 600 including heat exchanger 300 integrated into PV module 100. FIG. 7 is a cross sectional view of assembly 600 taken along the line A-A in FIG. 6.

In assembly 600, heat exchanger 300 is integrally formed with PV module 100 and does not need to be separately adhered to PV module 100. Moreover, heat exchanger 300 uses backsheet 506 of PV module 100 as inner layer 302. Spacer strips 602 extend between inner layer 302 (i.e., backsheet 506) and outer layer 306 to define cavity 305. Although not shown in FIGS. 6 and 7, cavity 305 also includes spacer 512. In this embodiment, spacer 512 is a metallic mesh 512 capable of withstanding the heat and pressure of lamination with PV module 100. In other embodiments, cavity 305 may include any other suitable filler and/or spacer. Outer layer 306 extends around spacer strips 602 to adhere heat exchanger 300 to PV module 100 and facilitate sealing cavity 305.

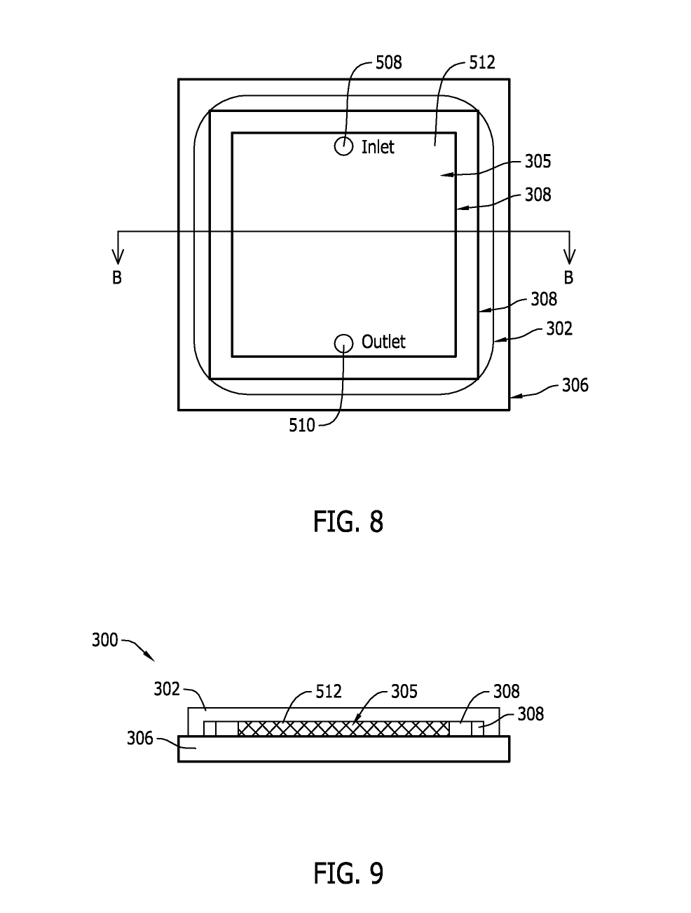

FIG. 8 is a top view of a stand-alone heat exchanger 300 of one embodiment. FIG. 9 is a cross sectional view of heat exchanger 300 taken along the line B-B in FIG. 8. The embodiment of heat exchanger 300 shown in FIGS. 8 and 9 is not integrally formed with any device and may be attached to any device, such as PV module 100, by any suitable type of attachment. In this embodiment, two sets of seals 308 are included around spacer 512.

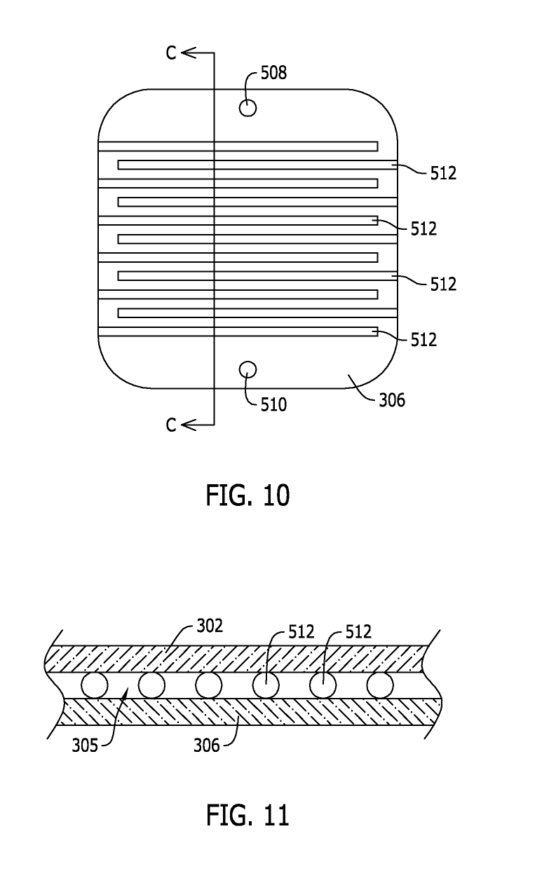

FIGS. 10 and 11 show an example heat exchanger 300 in which spacer 512 includes a parallel arrangement of plastic spacers. FIG. 10 is a top view, and FIG. 11 is a cross sectional view taken along the line C-C in FIG. 10. Heat exchanger 300 shown in FIGS. 10 and 11 may be integrated into a device or may be a standalone heat exchanger 300. The gap between adjacent spacers may be any suitable distance that ensures good fluid flow within the system to improve heat transfer and reduce bloating issues.

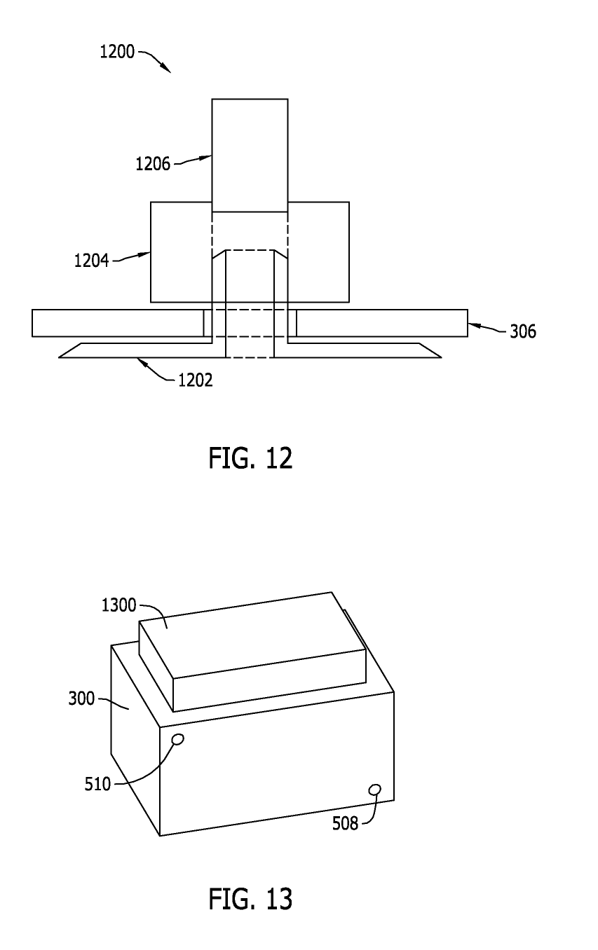

FIG. 12 is a partially schematic cross section of a suitable connection assembly 1200 for use at inlet 508 and/or outlet 510 of any embodiment of heat exchanger 300. Assembly 1200 includes a male component 1202 positioned inside exchanger 300 and extending through outer layer 306. A female component 1204 is positioned outside of heat exchanger 300 adjacent outer layer 306. Female component 1204 receives and surrounds the portion of male component 1202 that extends outside of heat exchanger 300. A portion of outer layer 306 is trapped between female component 1204 and male component 1202. Tubing 1206, used to transport thermal transfer fluid to and from heat exchanger 300, is inserted into female component 1204 to couple tubing 1206 to male component 1202. Assembly 1200 forms a liquid tight connection to heat exchanger 300. Thermal transfer fluid (e.g., a suitable coolant) may be transferred, via tubing 1206 and assembly 1200, from outside of heat exchanger 300 to the interior of heat exchanger 300, and vice versa.

FIG. 13 is a partially schematic view of heat exchanger 300 coupled to a device 1300. The device may be any suitable device that may benefit from temperature regulation provided by heat exchanger 300.

The heat exchangers and systems described herein generally provide inexpensive and effective ways to regulate temperature of a device, such as a PV module. Some embodiments of the heat exchangers disclosed herein can be integrated into the backsheet structure of a PV module using only an encapsulant and, thereby, can capitalize on existing manufacturing infrastructure and its economy of scale. Some embodiments of the heat exchangers can be used with a simple attachment mechanism to be affixed to nearly any PV modules, thereby making it field-retrofittable and easy to clean and/or replace. These heat exchangers are thus usable convert a conventional PV system or module into a PV-thermal system.

Moreover, coolant losses in the exemplary heat exchangers and systems will be negligible in a properly constructed system because coolant is retained within the system, i.e., it is a closed loop system, and there is no provision to allow coolant to intentionally escape. When used to cool PV modules, some heat exchangers of this disclosure have produced a decrease in PV module temperature of 18-20° C., and increased power output of the PV modules by about 10% at peak operating conditions. Other implementations may result in greater or lesser temperature reductions and/or greater or lesser increases in PV module efficiency.

When introducing elements of the present invention or the embodiment(s) thereof, the articles “a”, “an”, “the” and “said” are intended to mean that there are one or more of the elements. The terms “comprising”, “including” and “having” are intended to be inclusive and mean that there may be additional elements other than the listed elements.

As various changes could be made in the above without departing from the scope of the invention, it is intended that all matter contained in the above description and shown in the accompanying drawings shall be interpreted as illustrative and not in a limiting sense.

1. A photovoltaic (PV) module comprising:
a solar panel comprising a top surface and a bottom surface;
a heat exchanger in thermal communication with the bottom surface of the solar panel, wherein the heat exchanger comprises:
an outer layer;
a fluid chamber defined between the outer layer and the bottom surface of the solar panel;
an inlet for directing a thermal transfer fluid into the fluid chamber;
an outlet for receiving the thermal transfer fluid from the fluid chamber; and
at least one spacer within the fluid chamber, the spacer configured to control a flow of the thermal transfer fluid between the inlet and the outlet.

2-5. (canceled)

6. The PV module of claim 1, wherein the heat exchanger further comprises an inner layer between the fluid chamber and the bottom surface of the solar panel.

7. The PV module of claim 6, wherein the inner layer includes a thermally conductive material.

8. (canceled)

9. The PV module of claim 6, further comprising a thermal interface material positioned between the inner layer of the heat exchanger and the bottom layer of the solar panel.

10. The PV module of claim 6, wherein the heat exchanger is mechanically and in thermal communication with the bottom surface of the solar panel with a thermally conductive adhesive.

11. The PV module of claim 1, wherein the heat exchanger is integrally formed with the solar panel.

12. The PV module of claim 11, wherein the solar panel comprises a laminate structure, and the heat exchanger is laminated as part of the laminate structure.

13. A photovoltaic (PV) system comprising:
a fluid pump;
a fluid heat exchanger configured to thermally alter a thermal transfer fluid and provide the thermal transfer fluid to the fluid pump; and
a PV module coupled to the fluid pump and the fluid heat exchanger, the PV module configured to receive the thermal transfer fluid from the pump, the PV module comprising:
a solar panel including a top surface and a bottom surface; and
a heat exchanger in thermal communication with the bottom surface of the solar panel, the heat exchanger including a fluid chamber having at least one spacer within the fluid chamber, the heat exchanger configured to receive the thermal transfer fluid from the fluid pump into the fluid chamber and output the thermal transfer fluid to the fluid heat exchanger after the thermal transfer fluid has passed through the fluid chamber.

14. The PV system of claim 13, wherein the heat exchanger comprises:
an outer layer, the fluid chamber defined between the outer layer and the bottom surface of the solar panel;
an inlet for directing the thermal transfer fluid into the fluid chamber;
an outlet for receiving the thermal transfer fluid from the fluid chamber; and
wherein the at least one spacer within the fluid chamber is configured to control a flow of the thermal transfer fluid between the inlet and the outlet.

15-18. (canceled)

19. The PV system of claim 14, wherein the heat exchanger further comprises an inner layer between the fluid chamber and the bottom surface of the solar panel.

20. The PV system of claim 19, wherein the inner layer includes a thermally conductive material.

21. (canceled)

22. The PV system of claim 19, further comprising a thermal interface material positioned between the inner layer of the heat exchanger and the bottom layer of the solar panel.

23. The PV system of claim 19, wherein the heat exchanger is mechanically coupled to the bottom surface of the solar panel with a thermally conductive adhesive.

24. The PV system of claim 14, wherein the heat exchanger is integrally formed with the solar panel.

25. The PV system of claim 24, wherein the solar panel comprises a laminate structure, and the heat exchanger is laminated as part of the laminate structure.

26. A heat exchanger for coupling to a device to regulate a temperature of the device, the heat exchanger comprising:
an inner layer configured for placement against at least one surface of the device;
an outer layer opposite the inner layer;
a fluid chamber defined between the outer layer and the inner layer;
an inlet for directing a thermal transfer fluid into the fluid chamber;
an outlet for receiving the thermal transfer fluid from the fluid chamber; and
at least one spacer within the fluid chamber, the spacer coupled to the outer layer and the inner layer, the spacer configured to control a flow of the thermal transfer fluid between the inlet and the outlet.

27. The heat exchanger of claim 26, wherein the at least one spacer includes a metal mesh that substantially fills the fluid chamber.

28. The heat exchanger of claim 26, wherein the at least one spacer includes a sponge that substantially fills the fluid chamber.

29. The heat exchanger of claim 26, wherein the at least one spacer includes a plurality of spacers configured to direct the flow of thermal transfer fluid along a path having a length greater than a straight-line distance between the inlet and the outlet.

30. The heat exchanger of claim 29, wherein the plurality of spacers are arranged to direct the flow of thermal transfer fluid along a path having a plurality of 180 degree turns.

31-34. (canceled)

35. The PV module of claim 26, wherein the at least one spacer includes a sponge that substantially fills the fluid chamber.

36. A photovoltaic (PV) module comprising:
a solar panel comprising a top surface and a bottom surface;
a heat exchanger in thermal communication with the bottom surface of the solar panel, wherein the heat exchanger comprises:
an outer layer;
a fluid chamber defined between the outer layer and the bottom surface of the solar panel;
an inlet for directing a thermal transfer fluid into the fluid chamber; and
an outlet for receiving the thermal transfer fluid from the fluid chamber.

37. The PV system of claim 36, wherein the heat exchanger further comprises an inner layer between the fluid chamber and the bottom surface of the solar panel.

38. The PV system of claim 37, wherein the inner layer includes a thermally conductive material.

39. The PV system of claim 38, wherein the outer layer is configured to reduce bloating of the heat exchanger.
